(19) United States
(12) Patent Application Publication
(10) Pub. No.: US 2018/0121346 A1
(43) Pub. Date: May 3, 2018

(54) MEMORY APPARATUS AND OPERATING METHOD THEREOF

(71) Applicant: DAZZO TECHNOLOGY CORPORATION, Taipei City (TW)

(72) Inventors: Yu-Min Chang, Taipei City (TW); Tsorng-Yang Mei, Taipei City (TW); Yi-Ping Lee, Taipei City (TW)

(21) Appl. No.: 15/784,062

(22) Filed: Oct. 13, 2017

Related U.S. Application Data
(60) Provisional application No. 62/408,845, filed on Oct. 17, 2016.

(51) Int. Cl. G06F 12/02; G11C 13/00; G11C 11/4096; G11C 7/22; G11C 8/12

(52) U.S. Cl. CPC G06F 12/0246; G11C 13/0069; G11C 11/4096; G06F 3/0625; G11C 8/12; G06F 2212/1028; G11C 7/222

(57) ABSTRACT

A memory apparatus including memory modules, a command input module, a power supply module and a data access module is disclosed. Each memory module includes a memory bank including memory units. The command input module receives a non-random access command and generates a corresponding switch control signal according to the non-random access command. The power supply module is coupled to the command input module and the memory modules. The data access module is coupled to the command input module and the memory modules. At a first time, the power supply module selectively provides power only to a first memory module of the memory modules according to the switch control signal and the data access module will perform data access on the first memory module.

### BACKGROUND OF THE INVENTION

### 1. Field of the Invention

The invention relates to a memory; in particular, to a memory apparatus and an operating method thereof.

### 2. Description of the Prior Art

In general, in a system including the central processing unit (CPU), when the CPU access data stored in the memory apparatus (e.g., dynamic random access memory, DRAM) of the system, since the CPU accesses data randomly, it cannot be known in advance which memory unit in the memory apparatus will be accessed. That is to say, every memory unit in the memory apparatus is possible to be accessed. Therefore, in order to be randomly accessed by the CPU, most components in the memory apparatus must be powered to assume that the data can be accessed smoothly.

However, since the CPU only accesses a part of the memory units in the memory apparatus at one time, and other memory units will not be accessed at the same time, a lot of power is wasted and the power consumption of the memory apparatus fails to be effectively reduced; therefore, the power saving performance of the memory apparatus is poor.

### SUMMARY OF THE INVENTION

Therefore, embodiments of the invention provide a memory apparatus and an operating method thereof to overcome the above-mentioned problems in the prior art.

An embodiment of the invention is a memory apparatus. In this embodiment, the memory apparatus includes a plurality of memory modules, a command input module, a power supply module and a data access module. Each of the plurality of memory modules includes a bank respectively and the bank includes a plurality of memory units. The command input module is used to receive a non-random access command and generate a corresponding switch control signal according to the non-random access command. The power supply module is coupled to the command input module and the plurality of memory modules respectively. The data access module is coupled to the command input module and the plurality of memory modules respectively. At a first time, the power supply module selectively provides power only to a first memory module of the plurality of memory modules according to the switch control signal and the data access module performs data access on the first memory module.

In an embodiment, the memory apparatus is a dynamic random access memory (DRAM).

In an embodiment, at a second time, the power supply module selectively provides power only to a second memory module of the plurality of memory modules according to the switch control signal and the data access module performs data access on the second memory module.

In an embodiment, the non-random access command includes a regular and predictable read signal and/or a regular and predictable write signal.

In an embodiment, the non-random access command designates at least one memory module of the plurality of memory modules to be accessed.

In an embodiment, the non-random access command designates at least two memory modules of the plurality of memory modules to be accessed in order.

In an embodiment, the memory apparatus is coupled to a data processing apparatus, and the command input module receives the non-random access command from the data processing apparatus.

Another embodiment of the invention is a memory apparatus operating method. In this embodiment, the memory apparatus operating method is used for operating a memory apparatus including a plurality of memory modules, a command input module, a power supply module and a data access module. Each of the plurality of memory modules includes a bank respectively and the bank includes a plurality of memory units. The memory apparatus operating method includes steps of: the command input module receiving a non-random access command and generating a corresponding switch control signal according to the non-random access command; and at a first time, the power supply module selectively providing power only to a first memory module of the plurality of memory modules according to the switch control signal and the data access module performing data access on the first memory module.

Compared to the prior arts, data access is performed on the memory apparatus through regular and predictable non-random access command in the invention, since it is known in advance which memory unit in the memory apparatus will be accessed at certain time, the memory apparatus can only provide power to the memory module including that memory unit and other memory modules can be all powered off to save power. Therefore, the power consumption of the memory apparatus can be largely reduced and the power saving performance of the memory apparatus can be also effectively enhanced.

The advantage and spirit of the invention may be understood by the following detailed descriptions together with the appended drawings.

### BRIEF DESCRIPTION OF THE DRAWINGS

FIG. 1 and FIG. 2 illustrate schematic diagrams of the memory apparatus only providing power to a part of the memory modules in an embodiment of the invention.

FIG. 3 illustrates an embodiment of the non-random access command received by the command input module.

FIG. 4 and FIG. 5 illustrate an embodiment of the first memory module and the second memory module respectively.

FIG. 6 illustrates a flowchart of the memory apparatus operating method in another embodiment of the invention.

### DETAILED DESCRIPTION OF THE INVENTION

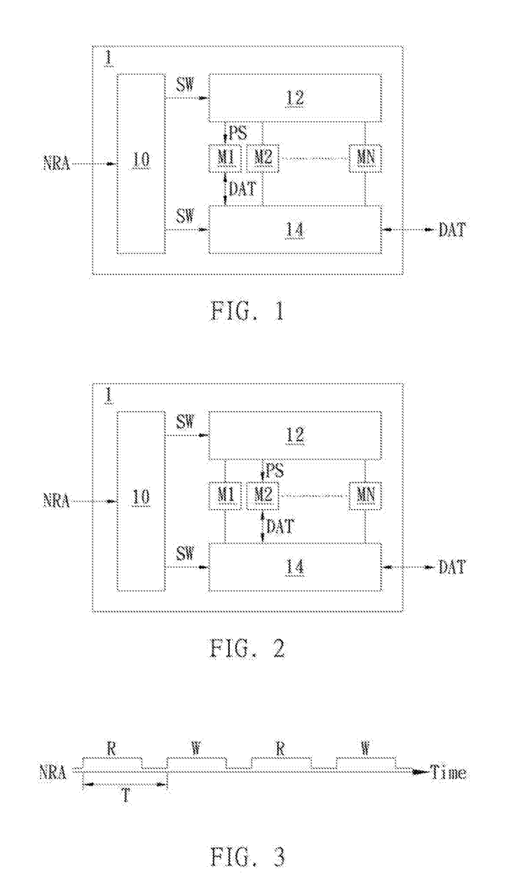

A preferred embodiment of the invention is a memory apparatus. In this embodiment, the memory apparatus can be a DRAM, but not limited to this. Please refer to FIG. 1 and FIG. 2. FIG. 1 and FIG. 2 illustrate schematic diagrams of the memory apparatus only providing power to a part of the memory modules in this embodiment.

As shown in FIG. 1 and FIG. 2, the memory apparatus 1 includes a command input module 10, a power supply module 12, a data access module 14 and N memory modules M1˜MN. The command input module 10 is coupled to the power supply module 12 and the data access module 14 respectively; the power supply module 12 is coupled to the N memory modules M1˜MN respectively; the data access module 14 is coupled to the N memory modules M1˜MN respectively.

In this embodiment, the command input module 10 is used to receive a non-random access command NRA and generate a corresponding switch control signal SW according to the non-random access command NRA. In practical applications, the memory apparatus 1 can be coupled to a data processing apparatus (e.g., the central processing unit, but not limited to this) and the non-random access command NRA received by the command input module 10 can be outputted by the data processing apparatus, but not limited to this.

It should be noticed that the memory apparatus in the prior arts receives random access command, such as an irregular and unpredictable read signal and/or an irregular and unpredictable write signal. On the contrary, the non-random access command NRA received by the command input module 10 in the memory apparatus 1 of the invention includes a regular and predictable read signal and/or a regular and predictable write signal, such as the periodic read signal R and periodic write signal W shown in FIG. 3. In an embodiment, the period T of the periodic read signal R and periodic write signal W can be 13 μs, but not limited to this.

In addition, the non-random access command NRA received by the command input module 10 in the memory apparatus 1 of the invention can designate at least one memory module of the N memory modules M1˜MN to be accessed or designate at least two memory modules of the N memory modules M1˜MN to be accessed in order.

Please refer to FIG. 1 and FIG. 2. If the non-random access command NRA designates a first memory module M1 and a second memory module M2 of the N memory modules M1˜MN to be accessed in order, then the command input module 10 will generate corresponding switch control signal SW according to the non-random access command NRA.

At a first time, as shown in FIG. 1, the power supply module 12 selectively provides power only to the first memory module M1 according to the switch control signal SW and the data access module 14 performs data access (e.g., reading or writing of the data DAT) on the first memory module M1. At this time, other memory modules M2˜MN of the N memory modules M1˜MN will be powered off without receiving any power from the power supply module 12 to reduce power consumption.

At a second time, as shown in FIG. 2, the power supply module 12 selectively provides power only to the second memory module M2 according to the switch control signal SW and the data access module 14 performs data access (e.g., reading or writing of the data DAT) on the second memory module M2. At this time, other memory modules M1 and M3˜MN of the N memory modules M1˜MN will be powered off without receiving any power from the power supply module 12 to reduce power consumption.

From above, it can be found that the invention can predict which memory module will be accessed in advance through the regular and predictable non-random access command; therefore, the power can be provided only to the memory module and other memory modules can be powered off at the same time to reduce unnecessary power waste.

In practical applications, each memory module of the N memory modules M1˜MN includes a bank respectively and each bank includes a plurality of memory units respectively. The plurality of memory units can be arranged as a matrix, but not limited to this.

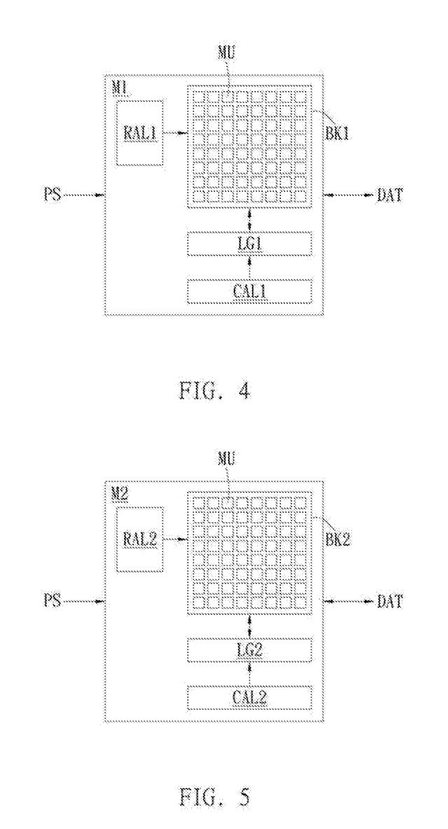

In an embodiment, as shown in FIG. 4, the first memory module M1 can include a first bank BK1, a first column address latch CAL1, a first row address latch RAL1 and a first logic unit LG1. The first row address latch RAL1 is coupled to the first bank BK1; the first column address latch CAL1 is coupled to the first logic unit LG1; the first logic unit LG1 is coupled to the first bank BK1.

It should be noticed that the first bank BK1 can include a memory matrix formed by the arrangement of the plurality of memory units MU used for storing data DAT. For example, if the data DAT that the non-random access command NRA wants to read is stored in the memory unit MU of the first bank BK1, since the first bank BK1 is disposed in the first memory module M1, the command input module 10 will generate corresponding switch control signal SW according to this non-random access command NRA, and the power supply module 12 will selectively provide power only to the first memory module M1 according to this switch control signal SW and the data access module 14 will read the data DAT stored in the memory unit MU of the first bank BK1, and so on.

In another embodiment, as shown in FIG. 5, the second memory module M2 can include a second bank BK2, a second column address latch CAL2, a second row address latch RAL2 and a second logic unit LG2. The second row address latch RAL2 is coupled to the second bank BK2; the second column address latch CAL2 is coupled to the second logic unit LG2; the second logic unit LG2 is coupled to the second bank BK2.

It should be noticed that the second bank BK2 can include a memory matrix formed by the arrangement of the plurality of memory units MU used for storing data DAT. For example, if the data DAT that the non-random access command NRA wants to read is stored in the memory unit MU of the second bank BK2, since the second bank BK2 is disposed in the second memory module M2, the command input module 10 will generate corresponding switch control signal SW according to this non-random access command NRA, and the power supply module 12 will selectively provide power only to the second memory module M2 according to this switch control signal SW and the data access module 14 will read the data DAT stored in the memory unit MU of the second bank BK2, and so on.

Another embodiment of the invention is a memory apparatus operating method. In this embodiment, the memory apparatus operating method is used for operating a memory apparatus. The memory apparatus can be a DRAM, but not limited to this.

The memory apparatus includes a plurality of memory modules, a command input module, a power supply module and a data access module. Each of the plurality of memory modules includes a bank respectively and the bank includes a plurality of memory units. The memory apparatus can be coupled to a data processing apparatus and receive a non-random access command from the data processing apparatus. In fact, the data processing apparatus can be a CPU, but not limited to this. It should be noticed that the non-random access command of the invention includes a regular and predictable read signal and/or a regular and predictable write signal different from the random access command of the prior art.

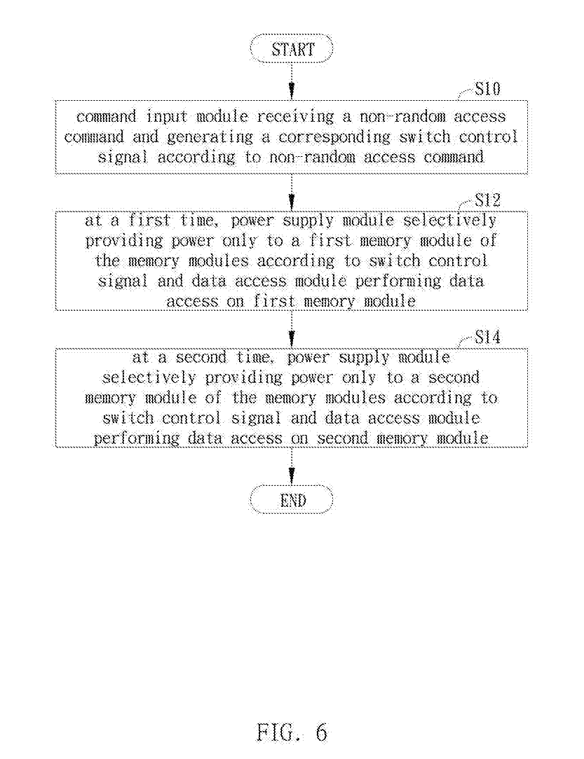

Please refer to FIG. 6. FIG. 6 illustrates a flowchart of the memory apparatus operating method in this embodiment. As shown in FIG. 6, the memory apparatus operating method includes following steps of:

Step S10: the command input module receiving a non-random access command and generating a corresponding switch control signal according to the non-random access command;

Step S12: at a first time, the power supply module selectively providing power only to a first memory module of the plurality of memory modules according to the switch control signal and the data access module performing data access on the first memory module; and

Step S14: at a second time, the power supply module selectively providing power only to a second memory module of the plurality of memory modules according to the switch control signal and the data access module performing data access on the second memory module.

In an embodiment, the non-random access command outputted by the data processing apparatus can designate at least one memory module (e.g., the first memory module) of the plurality of memory modules to be accessed. In Step S10, the command input module generates the switch control signal according to the non-random access command, so that the power supply module can be controlled to only provide power to the at least one memory module (e.g., the first memory module) in Step S12, but not limited to this.

In another embodiment, the non-random access command outputted by the data processing apparatus can also designate at least two memory modules (e.g., the first memory module and the second memory module) of the plurality of memory modules to be accessed. In Step S10, the command input module generates the switch control signal according to the non-random access command, so that the power supply module can be controlled to only provide power to one of the at least two memory modules (e.g., the first memory module) at the first time in Step S12 and only provide power to another of the at least two memory modules (e.g., the second memory module) at the second time in Step S14, but not limited to this.

Compared to the prior arts, data access is performed on the memory apparatus through regular and predictable non-random access command in the invention, since it is known in advance which memory unit in the memory apparatus will be accessed at certain time, the memory apparatus can only provide power to the memory module including that memory unit and other memory modules can be all powered off to save power. Therefore, the power consumption of the memory apparatus can be largely reduced and the power saving performance of the memory apparatus can be also effectively enhanced.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A memory apparatus, comprising:
a plurality of memory modules, wherein each of the plurality of memory modules comprises a bank respectively and the bank comprises a plurality of memory units;
a command input module used to receive a non-random access command and generate a corresponding switch control signal according to the non-random access command;
a power supply module coupled to the command input module and the plurality of memory modules respectively; and
a data access module coupled to the command input module and the plurality of memory modules respectively;
wherein at a first time, the power supply module selectively provides power only to a first memory module of the plurality of memory modules according to the switch control signal and the data access module performs data access on the first memory module.

2. The memory apparatus of claim 1, wherein the memory apparatus is a dynamic random access memory (DRAM).

3. The memory apparatus of claim 1, wherein at a second time, the power supply module selectively provides power only to a second memory module of the plurality of memory modules according to the switch control signal and the data access module performs data access on the second memory module.

4. The memory apparatus of claim 1, wherein the non-random access command comprises a regular and predictable read signal and/or a regular and predictable write signal.

5. The memory apparatus of claim 1, wherein the non-random access command designates at least one memory module of the plurality of memory modules to be accessed.

6. The memory apparatus of claim 1, wherein the non-random access command designates at least two memory modules of the plurality of memory modules to be accessed in order.

7. The memory apparatus of claim 1, wherein the memory apparatus is coupled to a data processing apparatus, and the command input module receives the non-random access command from the data processing apparatus.

8. A memory apparatus operating method used for operating a memory apparatus comprising a plurality of memory modules, a command input module, a power supply module and a data access module, each of the plurality of memory modules comprising a bank respectively and the bank comprising a plurality of memory units, the memory apparatus operating method comprising steps of:
the command input module receiving a non-random access command and generating a corresponding switch control signal according to the non-random access command; and
at a first time, the power supply module selectively providing power only to a first memory module of the plurality of memory modules according to the switch control signal and the data access module performing data access on the first memory module.

9. The memory apparatus operating method of claim 8, wherein the memory apparatus is a dynamic random access memory (DRAM).

10. The memory apparatus operating method of claim 8, wherein at a second time, the power supply module selectively provides power only to a second memory module of the plurality of memory modules according to the switch control signal and the data access module performs data access on the second memory module.

11. The memory apparatus operating method of claim 8, wherein the non-random access command comprises a regular and predictable read signal and/or a regular and predictable write signal.

12. The memory apparatus operating method of claim 8, wherein the non-random access command designates at least one memory module of the plurality of memory modules to be accessed.

13. The memory apparatus operating method of claim 8, wherein the non-random access command designates at least two memory modules of the plurality of memory modules to be accessed in order.

14. The memory apparatus operating method of claim 8, wherein the memory apparatus is coupled to a data processing apparatus, and the command input module receives the non-random access command from the data processing apparatus.
